(19) United States
(12) Patent Application Publication
(10) Pub. No.: US 2026/0020458 A1
(43) Pub. Date: Jan. 15, 2026

(54) DISPLAY DEVICE AND ELECTRONIC DEVICE INCLUDING THE SAME

(71) Applicant: Samsung Display Co., Ltd., Yongin-si (KR)

(72) Inventors: EUNBYUL KIM, Yongin-si (KR); HANBUM KWON, Yongin-si (KR); YOUNGMIN AHN, Yongin-si (KR)

(21) Appl. No.: 19/263,305

(22) Filed: Jul. 8, 2025

(30) Foreign Application Priority Data
Jul. 10, 2024 (KR) 10-2024-0091072

(51) Int. Cl. H10K 59/131; H10K 59/121; H10K 59/124; H10K 59/40; H10K 59/80

(52) U.S. Cl. CPC H10K 59/131; H10K 59/1213; H10K 59/124; H10K 59/40; H10K 59/873

(57) ABSTRACT

A display device includes a base substrate having an active region and a peripheral region adjacent to the active region, a circuit element layer including a barrier layer on the base substrate, insulating layers on the barrier layer, and transistors each including conductive patterns between the insulating layers, a display element layer including light-emitting elements connected to the transistors, display pads in a peripheral region and connected to the transistors, a circuit board including board pads coupled to the display pads, and a film layer between the display pads and the board pads, wherein side surfaces of the insulating layers define a groove, the groove exposing a portion of the barrier layer and located between adjacent display pads of the display pads, and the film layer is in contact with the portion of the barrier payer exposed by the groove.

### CROSS-REFERENCE TO RELATED APPLICATION

The present application claims priority to and the benefit of Korean Patent Application No. 10-2024-0091072, filed on Jul. 10, 2024, in the Korean Intellectual Property Office, the entire disclosure (e.g., amount) of which is incorporated herein by reference.

### BACKGROUND

Embodiments of the present disclosure relate to a display device and, for example, to a pad region of a display device. Additional embodiments relate to an electronic device including the display device.

A display device includes a display region which is activated in response to an electrical signal. The display device may sense an input applied from the outside and may display one or more suitable images to provide information to a user through the display region.

In the display device, pads of a display panel and pads of a circuit board may be connected to each other. A bumpless structure may be applied to the pads of the circuit board to prevent or reduce the likelihood of short circuits, and/or the like.

The above information disclosed in this Background section is intended to enhance understanding of the background of the disclosure and may contain information that does not constitute prior art.

### SUMMARY

Aspects of one or more embodiments of the present disclosure are directed to a display device capable of improving bonding force between pads of a display panel and pads of a circuit board in a bumpless structure.

Aspects of one or more embodiments of the present disclosure are directed to a display device capable of improving bonding force between pads of a display panel and pads of a circuit board and mechanical strength of the display panel by increasing the contact between the display and circuit board pads in an area adjacent to the pads.

Additional aspects will be set forth in part in the description which follows and, in part, will be apparent from the description, or may be learned by practice of the presented embodiments of the disclosure.

One or more embodiments of the present disclosure provide a display device including a base substrate having an active region and a peripheral region adjacent to the active region, a circuit element layer including a barrier layer arranged on the base substrate, insulating layers arranged on the barrier layer, and transistors each including conductive patterns arranged between the insulating layers, a display element layer including light-emitting elements connected to the transistors, display pads arranged in the peripheral region and connected to the transistors, a circuit board including board pads coupled to the display pads, and a film layer arranged between the display pads and the board pads, wherein side surfaces of the insulating layers define a groove, the groove exposing a portion of the barrier layer is and located between the adjacent display pads of the display pads, and the film layer is in contact with the portion of the barrier layer exposed by the groove.

In one or more embodiments, the side surfaces of the insulating layers defining the groove may be inclined at a set or predetermined angle.

In one or more embodiments, the side surfaces of the insulating layers defining the groove may be aligned with each other.

In one or more embodiments, a width, e.g., a width in one direction, of a space between the side surfaces of the insulating layers defining the groove may increase in a direction away from the base substrate.

In one or more embodiments, the display pads may be arranged along a first direction and a second direction intersecting the first direction, each of the display pads may extend along the second direction, and display pads of the display pads that are sequentially arranged along the first direction may be defined as one pad row.

In one or more embodiments, the groove includes a plurality of grooves and each of the grooves may be arranged between adjacent display pads of the display pads arranged in the same pad row, and the grooves may be spaced and/or apart (e.g., spaced apart or separated) from each other along the first direction and the second direction.

In one or more embodiments, widths of the grooves may be in the first direction and may vary along the second direction.

In one or more embodiments, the display device may further include pad lines connecting the display pads and the transistors and may be arranged between the display pads and the grooves adjacent to the display pads, wherein a first width of a first groove among the grooves may be larger than a second width of a second groove among the grooves, the first and second width measured along the first direction, and a number of the pad lines adjacent to the first groove in the first direction may be less than the number of the pad lines adjacent the second groove in the first direction.

In one or more embodiments, the grooves may be arranged along the first direction, the grooves may each of the grooves may extend along the second direction, the display pads may be sequentially arranged along the first direction in a plurality of pad rows, the pad rows arranged along the second direction; and when viewed in the first direction, a groove of the grooves may overlap the display pads of at least two different pad rows of the pad rows.

In one or more embodiments, the grooves may each include sub grooves spaced and/or apart (e.g., spaced apart or separated) from each other along the second direction, and the sub grooves of each of the grooves may be arranged between adjacent display pads of the display pads arranged in the same pad row.

In one or more embodiments, the insulating layers may include a buffer layer arranged on the barrier layer, and first to seventh insulating layers arranged on the buffer layer, one of the transistors may include a first semiconductor pattern arranged on the buffer layer, a first control electrode arranged on the first insulating layer and overlapping the first semiconductor pattern, and an upper electrode arranged on the second insulating layer and overlapping the first control electrode, another of the transistors may include a second semiconductor pattern arranged on the third insulating layer and a second control electrode arranged on the fourth insulating layer and overlapping the second semiconductor pattern, the display device may further include an input electrode and an output electrode arranged on the fifth insulating layer and connected to the first and second semiconductor patterns through contact holes and a connection electrode arranged on the sixth insulating layer and connected to the input electrode, and at least one of the light-emitting elements may include a first electrode connected to the connection electrode through a contact hole in the seventh insulating layer.

In one or more embodiments, the display device may further include an encapsulation layer covering the display element layer, the encapsulation layer including inorganic layers and an organic layer arranged between the inorganic layers, and an input sensor directly arranged on the encapsulation layer, wherein the input sensor may include a first sensing insulating layer arranged on the encapsulation layer, a first conductive layer arranged on the first sensing insulating layer, a second sensing insulating layer arranged on the first sensing insulating layer, a second conductive layer arranged on the second sensing insulating layer, and a third sensing insulating layer arranged on the second sensing insulating layer.

In one or more embodiments, the display pads may each include a first pattern arranged on the second insulating layer, a second pattern arranged on the first pattern, a third pattern arranged on the second pattern, and a fourth pattern arranged on the third pattern, the second pattern may be arranged in a first opening penetrating (e.g., defined by) the second to fifth insulating layers, and the fourth pattern may be arranged in a second opening penetrating (e.g., defined by) the first and second sensing insulating layers.

In one or more embodiments, the first pattern may include the same material as the first semiconductor pattern, the second pattern may include the same material as the input electrode, the third pattern may include the same material as the connection electrode, and the fourth pattern may include the same material as the second conductive layer.

In one or more embodiments, the film layer may be an anisotropic conductive film (ACF) including a resin and conductive particles arranged inside the resin.

In one or more embodiments, the display pads may each include a first conductive pattern, an insulating pattern arranged on the first conductive pattern and including a polymer, and a second conductive pattern covering the insulating pattern and having two ends connected to the first conductive pattern, and the second conductive pattern may be in direct contact with a board pad of the board pads.

In one or more embodiments, the film layer may be a non-conductive film (NCF) including a resin (e.g., including only a resin).

In one or more embodiments, the display device may further include dam patterns arranged inside the groove and arranged along a direction in which the groove extends, wherein the dam patterns may include the same material as at least one of the insulating layers.

In one or more embodiments, the board pads may each include a first pad layer, a second pad layer arranged under the second pad layer, and a third pad layer arranged under the second pad layer, and the first to third pad layers may include different materials.

In one or more embodiments, the first pad layer may include aluminum (Al), the second pad layer may include an under bump metallization (UBM) material, and the third pad layer may include gold (Au).

One or more embodiments of the present disclosure provide an electronic device including a display device including a base substrate having an active region and a peripheral region adjacent to the active region, a circuit element layer including a barrier layer arranged on the base substrate, insulating layers arranged on the barrier layer, and transistors each including conductive patterns arranged between the insulating layers, a display element layer including light-emitting elements connected to the transistors, display pads arranged in the peripheral region and connected to the transistors, a circuit board including board pads coupled to the display pads, and a film layer arranged between the display pads and the board pads, wherein side surfaces of the insulating layers define a groove, the groove exposing a portion of the barrier layer is and located between the adjacent display pads of the display pads, and the film layer is in contact with the portion of the barrier layer exposed by the groove.

In one or more embodiments, the electronic device may be a smart watch, a tablet PC, a laptop, a computer, or a smart television.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to one or more embodiments of the present disclosure;

FIG. 2 is an exploded perspective view of a display device according to one or more embodiments of the present disclosure;

FIG. 3 is a cross-sectional view taken along the line I-I′ of FIG. 2, according to one or more embodiments of the present disclosure;

FIG. 4 is a cross-sectional view of a display device illustrating a state in which a display panel is bent, according to one or more embodiments of the present disclosure;

FIG. 5 is a plan view of a display panel according to one or more embodiments of the present disclosure;

FIG. 6 is a plan view of an input sensor according to one or more embodiments of the present disclosure;

FIG. 7 is a cross-sectional view of a portion of a display module according to one or more embodiments of the present disclosure;

FIG. 8 is a cross-sectional view of pads coupled to each other according to one or more embodiments of the present disclosure;

FIG. 9 is a cross-sectional view of pads coupled to each other according to one or more embodiments of the present disclosure;

FIG. 10 is a plan view of a portion of a pad region according to one or more embodiments of the present disclosure;

FIG. 11A is a cross-sectional view taken along the line I-I′ of FIG. 10, according to one or more embodiments of the present disclosure;

FIG. 11B is a cross-sectional view taken along the line II-II′ of FIG. 10, according to one or more embodiments of the present disclosure;

FIG. 12 is a cross-sectional view of pads coupled to and/or adjacent to each other and taken along the line I-I′ of FIG. 10, according to one or more embodiments of the present disclosure;

FIG. 13 is a plan view of a portion of a pad region according to one or more embodiments of the present disclosure;

FIG. 14 is a plan view of a portion of a pad region according to one or more embodiments of the present disclosure;

FIG. 15 is a plan view of a portion of a pad region according to one or more embodiments of the present disclosure;

FIG. 16A is a plan view of a portion of a pad region according to one or more embodiments of the present disclosure; and

FIG. 16B is a cross-sectional view taken along the line III-III′ of FIG. 16A, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity. Also, in the drawings, the thicknesses, ratios, and dimensions of the elements may be exaggerated for effective description of the technical contents.

As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction DR1 and the second direction DR2. This refers to that in a plan view, the arrangement of sub-pixels, pads, and other components as they are laid out on the substrate can be seen, without any perspective distortion.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments of the present disclosure will be described with reference to the drawings.

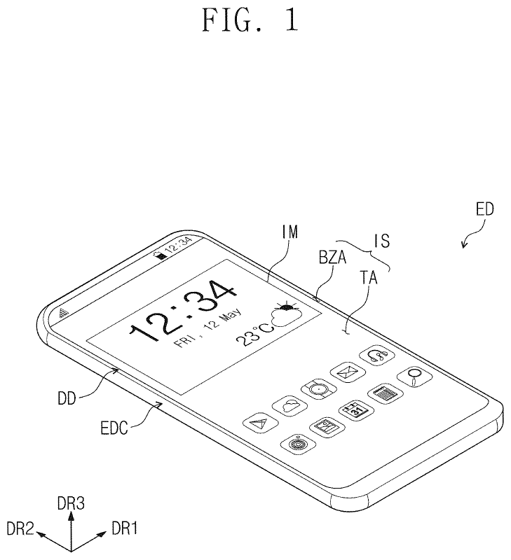

Referring to FIGS. 1 to 3, an electronic device ED may be activated in response to an electrical signal. The electronic device ED may include one or more suitable embodiments. For example, the electronic device ED may be (e.g., may include) a display device such as a smart watch, a tablet PC, a laptop, a computer, and a smart television.

The electronic device ED may display an image IM in a third direction DR3 on a display surface IS parallel to each of a first direction DR1 and a second direction DR2. The display surface IS on which the image IM is displayed may correspond to a front surface of the electronic device ED. The image IM may include a static image as well as a dynamic image.

In one or more embodiments, a front surface (or an upper surface) and a rear surface (or a lower surface) of each of members are defined on the basis of the third direction DR3 in which the image IM is displayed. A front surface and a rear surface are opposed to each other in the third direction DR3, and a normal direction of each of a front surface and a rear surface may be parallel to the third direction DR3.

A distance between a front surface and a rear surface in the third direction DR3 may correspond to a thickness of the electronic device ED in the third direction DR3. In the present disclosure, directions indicated by first to third directions DR1, DR2, and DR3 are relative concepts and may be changed to other directions.

The electronic device ED may sense an external input applied from the outside. The external input may include inputs in one or more suitable forms, which are provided from the outside. For example, the external input may include not only an external input such as contact by a body part, such as a user's hand, but also an external input (for example, hovering) applied close to the electronic device ED or applied adjacent to the electronic device ED at a set or predetermined distance. In one or more embodiments, the external input may include one or more suitable forms, such as force, pressure, temperature, and light.

The display surface IS of the electronic device ED may be divided into a transmission region TA and a bezel region BZA. The transmission region TA may be a region in which the image IM is displayed. A user views the image IM through the transmission region TA. In one or more embodiments, the transmission region TA may have a quadrangular shape with round vertices as shown, for example, in FIG. 1. However, this is illustrated as an example, and the transmission region TA may have one or more suitable shapes and is not limited to any one embodiment.

The bezel region BZA is adjacent to the transmission region TA. The bezel region BZA may have a set or predetermined color. The bezel region BZA may be around (e.g., surround) the transmission region TA. Accordingly, a shape of the transmission region TA may be substantially defined by the bezel region BZA. However, this is illustrated as an example, and the bezel region BZA may be arranged to be adjacent to only one or more sides of the transmission region TA or may not be provided. The electronic device ED according to one or more embodiments of the present disclosure may include one or more suitable modifications and is not limited to any one embodiment.

The electronic device ED may include a display device DD and an external case EDC (or a housing). The display device DD may include a window WM, a display module DM, a driving module EM, an optical film OTF, and a lower module LM. The display module DM may include a display panel DP and an input sensor ISP arranged on the display panel DP. The display panel DP generates the image IM, and the input sensor ISP obtains coordinate information about an external input (for example, a touch event).

The window WM may include a transparent material through which an image may be emitted. For example, the window WM may include glass, sapphire, plastic, and/or the like. The window WM is illustrated as a single layer, but the present disclosure is not limited thereto and may include a plurality of layers. In one or more embodiments, the bezel region BZA of the display device DD described above may be substantially provided as a region in which a material including a set or predetermined color is printed in one region of the window WM.

The display module DM may include the display panel DP and the input sensor ISP. The display panel DP according to one or more embodiments of the present disclosure may be an emissive display panel but is not particularly limited thereto. For example, the display panel DP may be an organic light-emitting display panel, an inorganic light-emitting display panel, or a quantum dot light-emitting display panel. An emission layer of the organic light-emitting display panel may include an organic light-emitting material, and an emission layer of the inorganic light-emitting display panel may include an inorganic light-emitting material. An emission layer of the quantum dot light-emitting display panel may include quantum dots, quantum rods, and/or the like. Hereinafter, the display panel DP will be described as an organic light-emitting display panel.

The input sensor ISP may be “directly arranged” on the display panel DP. According to one or more embodiments of the present disclosure, the input sensor ISP may be formed on the display panel DP through a substantially continuous process. For example, in embodiments in which the input sensor ISP is directly arranged on the display panel DP, an adhesive film for coupling the input sensor ISP and the display panel DP is not arranged between the input sensor ISP and the display panel DP.

The optical film OTF reduces reflectance of external light incident from above the window WM. The optical film OTF according to one or more embodiments of the present disclosure may include a retarder and a polarizer. The retarder may be a film-type (kind) retarder or a liquid crystal coating-type (kind) retarder and include a λ/2 retarder and/or a λ/4 retarder. The polarizer may also be a film-type (kind) polarizer or a liquid crystal coating-type (kind) polarizer. The film type (kind) may include a stretchable synthetic resin film, and the liquid crystal coating type (kind) may include liquid crystals arranged in a set or predetermined arrangement. The retarder and the polarizer may be implemented as one polarizing film. The optical film OTF may further include a protective film arranged above or below the polarizing film.

The optical film OTF may be arranged on the input sensor ISP. For example, the optical film OTF may be arranged between the input sensor ISP and the window WM. The input sensor ISP, the optical film OTF, and the window WM may be coupled to each other through an adhesive layer.

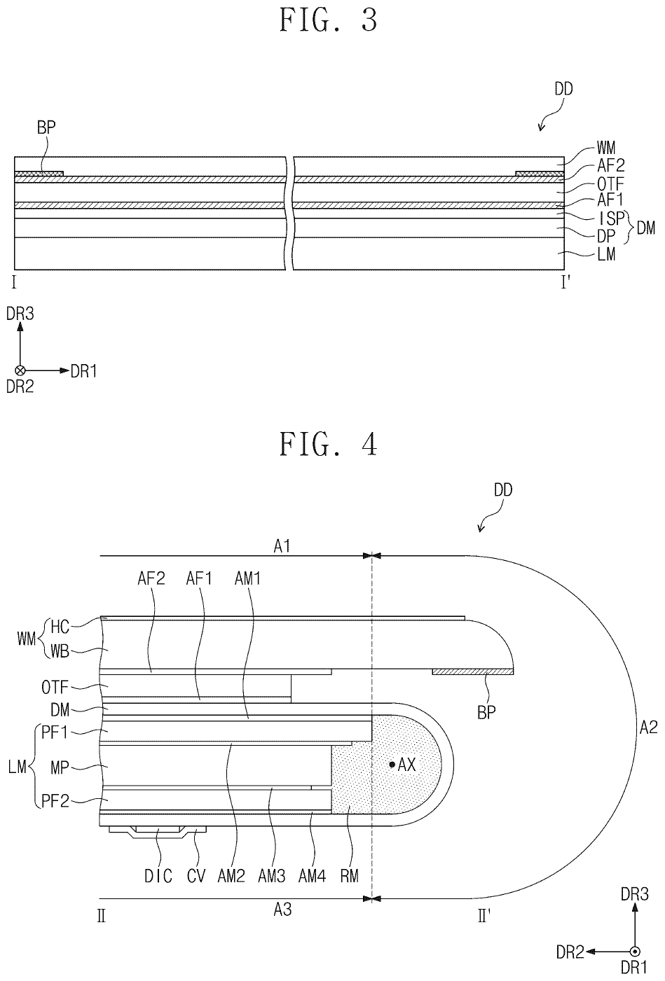

Referring to FIG. 3, an optical adhesive layer AF1 is arranged between the input sensor ISP and the optical film OTF, and a window adhesive layer AF2 is arranged between the optical film OTF and the window WM. Thus, the optical film OTF is coupled to the input sensor ISP by the optical adhesive layer AF1, and the window WM is coupled to the optical film OTF by the window adhesive layer AF2.

As an example of the present disclosure, the adhesive layers AF1 and AF2 may each include an optically clear adhesive (OCA) film. However, a material of each of the adhesive layers AF1 and AF2 is not limited thereto and may include any suitable, generally available and/or generally utilized adhesive or bonding agent. For example, the adhesive layers AF1 and AF2 may each include a pressure sensitive adhesive (PSA), an optical clear adhesive (OCA), or an optical clear resin (OCR).

A functional layer, for example, a protective layer, and/or the like, which performs a different function, may be further arranged between the display module DM and the window WM in addition to the optical film OTF.

The display module DM may display an image in response to an electrical signal and may transmit and/or receive information about an external input. The display module DM may be defined as an active region AA and a peripheral region NAA. The active region AA may be defined as a region in which an image from the display module DM is provided.

The peripheral region NAA is adjacent to the active region AA. For example, the peripheral region NAA may be around (e.g., surround) the active region AA. However, this is illustrated as an example, and the peripheral region NAA may be defined in one or more suitable shapes and is not limited to any one embodiment. According to one or more embodiments, the active region AA of the display module DM may correspond to at least a portion of the transmission region TA.

According to embodiments of the present disclosure, the display module DM may include a first region A1, a second region A2, and a third region A3 arranged along the second direction DR2. The first region A1 may include a portion of the peripheral region NAA and the active region AA, and the second region A2 and the third region A3 may include the rest of the peripheral region NAA. The second region A2 may be a bending region that is bent with respect to a bending axis, and the first region A1 and the third region A3 may each be a non-bending region.

A length of each of the second region A2 and the third region A3 in the first direction DR1 may be smaller than or equal to a length of the first region A1 in the first direction DR1. Because the display module DM according to embodiments of the present disclosure includes a region having a relatively small length that is bent with respect to a bending axis, the second region A2 may be allowed to be more easily bent. The third region A3 may be arranged below the first region A1 and accommodated in the external case EDC in a state in which the second region A2 is bent.

The driving module EM may control driving of the display module DM. The driving module EM may include a flexible circuit film (e.g., flexible circuit board) FCB and a driving chip DIC. The flexible circuit film FCB may be electrically connected to the display panel DP. The flexible circuit film FCB may be coupled to an end of the third region A3 of the display module DM through a bonding process. The flexible circuit film FCB may be electrically connected to the display module DM through an anisotropic conductive adhesive layer. The driving chip DIC may be mounted on the third region A3 of the display module DM. The driving chip DIC may include driving circuits, for example, a data driving circuit for driving pixels of the display panel DP.

According to one or more embodiments, the flexible circuit film FCB may include a ground line for discharging static electricity that is introduced to the flexible circuit film FCB or to the input sensor ISP.

The driving module EM may further include a plurality of driving elements mounted on the flexible circuit film FCB. The plurality of driving elements may include a circuit unit for converting a signal input from the outside into a signal for the driving chip DIC or a signal for driving the display module DM. When the second region A2 and the third region A3 of the display module DM are bent, the flexible circuit film FCB may be arranged below the display module DM.

The lower module LM may be arranged on a rear surface of the display module DM. If (e.g., when) the lower module LM is arranged on the rear surface of the display module DM, the lower module LM may improve impact resistance of the display device DD. The lower module LM may be fixed to the rear surface of the display module DM through an adhesive layer.

When the second region A2 and the third region A3 of the display module DM are bent, the third region A3 of the display module DM and the flexible circuit film FCB may be arranged on a rear surface of the lower module LM.

The external case EDC may be coupled to the window WM to define an exterior of the electronic device ED. The external case EDC accommodates the display device DD. The external case EDC protects components accommodated in the external case EDC by absorbing an impact applied from the outside and preventing or reducing (e.g., protecting from) foreign substances/moisture, and/or the like, from infiltrating into the electronic device ED. In one or more embodiments, the external case EDC may be provided in a form in which a plurality of accommodation members are coupled to each other.

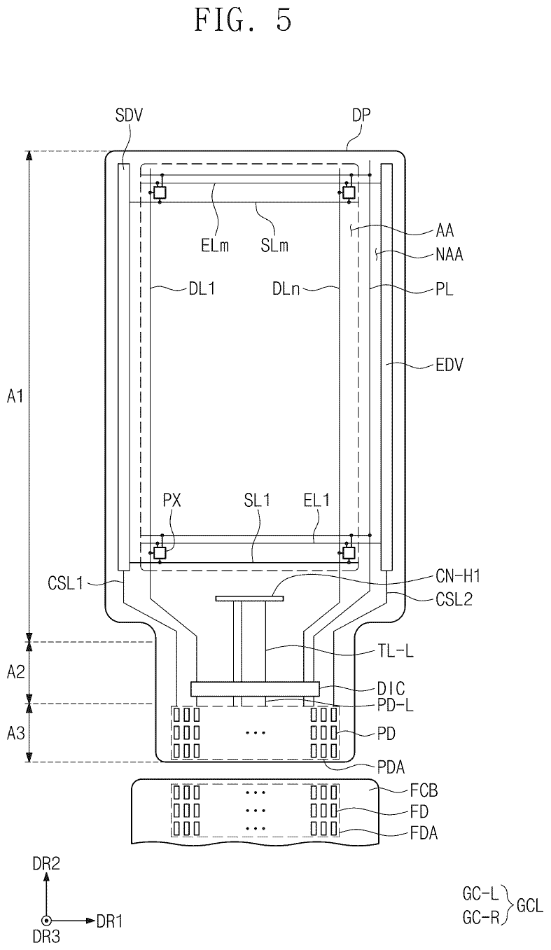

FIG. 4 is a cross-sectional view of a display device illustrating a state in which a display panel is bent, according to one or more embodiments of the present disclosure. FIG. 4 is a cross-sectional view of a portion of a display device DD adjacent to a second region A2, in a state in which the second region A2 is bent with respect to a bending axis AX extending along the first direction DR1.

The display device DD may include a window WM, an optical film OTF, a display module DM, and a lower module LM. The lower module LM may include a first protective member PF1, a second protective member PF2, and a functional layer MP.

The window WM according to one or more embodiments may include a base portion WB, a hard coating layer HC, and a bezel pattern BP. The base portion WB may include an optically transparent insulating material. For example, the base portion WB may include a glass substrate or a synthetic resin film. The hard coating layer HC for protecting the base portion WB may be arranged on a front surface and/or a rear surface of the base portion WB. The hard coating layer HC may prevent or reduce the likelihood of the base portion WB being damaged by a scratch, and/or the like. In one or more embodiments, an anti-fingerprint layer may be further arranged on the base portion WB.

The bezel pattern BP defines the bezel region BZA (see, e.g., FIG. 1) of the window WM. The bezel pattern BP may be arranged to be adjacent to an edge of the rear surface of the base portion WB.

The bezel pattern BP may be a colored layer which is formed by a coating method. The bezel pattern BP may include a polymer resin and a pigment that is mixed with the polymer resin. The polymer resin may be, for example, an acrylic resin or polyester, and the pigment may be a carbon-based pigment.

The optical film OTF may be arranged below the window WM. The optical film OTF may reduce reflectance of external light incident from the window WM. The window WM and the optical film OTF may be coupled to each other through a window adhesive layer AF2. The display module DM and the optical film OTF may be coupled to each other through an optical adhesive layer AF1.

The lower module LM may include the first protective member PF1, the functional layer MP, and the second protective member PF2. The lower module LM may be arranged between a first region A1 and a third region A3 in a state in which the second region A2 is bent. The lower module LM and the display module DM may be coupled to each other through a first adhesive layer AM1.

The functional layer MP may be arranged below the first protective member PF1. The functional layer MP and the first protective member PF1 may be coupled to each other through a second adhesive layer AM2. The functional layer MP may be provided in a plate shape (e.g., may be substantially flat). The functional layer MP may include a plurality of layers. For example, the functional layer MP may include a light blocking layer, a heat dissipation layer, a cushion layer, and a plurality of adhesive layers.

The light blocking layer may serve to address and/or resolve the issue in which components arranged in the display module DM are visible in the active regions AA through the window WM. The light blocking layer may include a binder and a plurality of pigment particles dispersed therein. The pigment particles may include carbon black, and/or the like. The electronic device ED according to one or more embodiments may have an effect of improving a light shielding property because the electronic device ED includes a light blocking layer.

The heat dissipation layer may effectively dissipate heat generated in the display module DM. The heat dissipation layer may include at least one of aluminum (Al), copper (Cu), or graphite having excellent or suitable heat dissipation characteristics. However, the present disclosure is not limited thereto. The heat dissipation layer may not only improve heat dissipation characteristics but also have electromagnetic wave shielding or electromagnetic wave absorbing characteristics.

The cushion layer may be synthetic resin foam. The cushion layer may include a matrix and a plurality of pores. The cushion layer may have elasticity and a porous structure.

The matrix may include a flexible material. The matrix may include a synthetic resin. For example, the matrix may include at least one of acrylonitrile butadiene styrene copolymer (ABS), polyurethane (PU), polyethylene (PE), ethylene vinyl acetate (EVA), or polyvinyl chloride (PVC). The plurality of pores may absorb (e.g., easily absorb) an impact applied to the cushion layer. The plurality of pores may be defined because the cushion layer has a porous structure.

According to one or more embodiments, at least one of a light blocking layer, a heat dissipation layer, or a cushion layer included in the functional layer MP may not be provided, and/or a plurality of layers may be provided as a single layer. However, the present disclosure is not limited to any one embodiment.

The functional layer MP and the second protective member PF2 may be coupled to each other by a third adhesive layer AM3. The second protective member PF2 may be arranged on a rear surface of the display module DM overlapping the third region A3 and the first region A1 in a plan view. The display module DM and the second protective member PF2 may be coupled to each other through a fourth adhesive layer AM4.

The electronic device ED according to one or more embodiments may include a protective layer RM. The protective layer RM may be arranged in an internal space which is defined at the rear surface of the display module DM overlapping the second region A2 if (e.g., when) the display module DM is bent, a side surface of the first protective member PF1, a side surface of the functional layer MP, a side surface of the second protective member PF2, and a side surface of each of the adhesive layers AM1, AM2, AM3, and AM4.

Because the protective layer RM is arranged in the internal space, the protective layer RM may support the display module DM so that the form of the second region A2 is capable of being maintained when the display module DM is bent. For example, the protective layer may provide a support structure to support and provide the curved shape of the display module DM around the bending axis AX and to support the structural integrity of the display module DM when the display module DM is bent. In one or more embodiments, the protective layer RM may prevent or reduce the likelihood of (e.g., protect from) foreign substances, and/or the like, being introduced into the display module DM through the second region A2. The protective layer RM according to one or more embodiments may include a resin.

The display panel DP according to one or more embodiments may further include a bending cover layer arranged on the second region A2. The bending cover layer may reduce stress applied to the second region A2 when the second region A2 is bent and may protect the second region A2.

The display device DD according to one or more embodiments may further include a conductive film CV arranged in the third region A3. The conductive film CV may cover a driving chip DIC to prevent or reduce static electricity introduced from the outside from damaging the driving chip DIC and/or to prevent or reduce the likelihood of (e.g., protect from) foreign substances, and/or the like, from being introduced into the driving chip DIC. In one or more embodiments, the conductive film CV may prevent or reduce the likelihood of an impact from being applied to and/or from effecting the driving chip DIC.

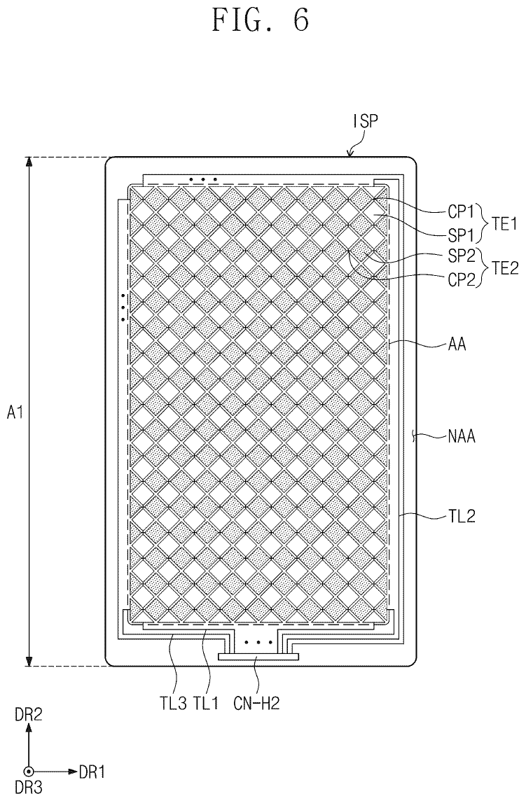

FIG. 5 is a plan view of a display panel according to one or more embodiments of the present disclosure.

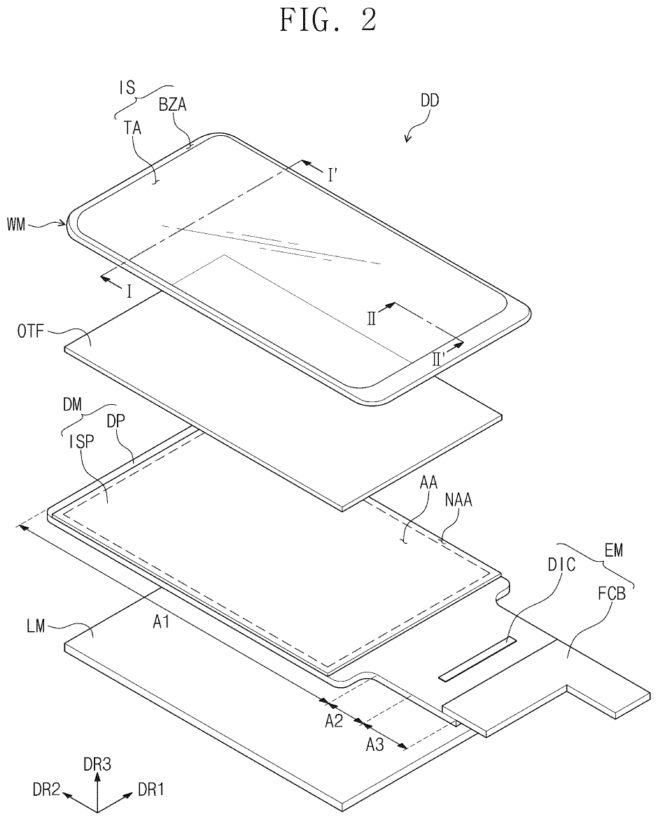

A display panel DP according to one or more embodiments of the present disclosure may be divided into a first region A1, a second region A2, and a third region A3 arranged along the second direction DR2. The first to third regions A1, A2, and A3 of the display panel DP illustrated in FIG. 5 respectively correspond to the first to third regions A1, A2, and A3 of the display module DM described with reference to FIG. 2. As used herein, the wording “a region/portion corresponds to a region/portion” refers to that the regions/portions overlap, and is not limited to meaning that the regions/portions have the same area.

The display panel DP according to one or more embodiments may include an active region AA in which a pixel PX (e.g., a plurality of pixels PX) is arranged and a peripheral region NAA adjacent to the active region AA. The active region AA and the peripheral region NAA respectively correspond to the active region AA and the peripheral region NAA described with reference to FIG. 2. The active region AA corresponds to a region of the first region A1 in which the pixel PX is arranged, and the peripheral region NAA is defined as a remaining region excluding the region in which the pixel PX is arranged.

The first region A1 may include a portion of the peripheral region NAA and the active region AA, and the second region A2 and the third region A3 may include a remaining portion of the peripheral region NAA.

The display panel DP may include a scan driver SDV, an emission driver EDV, display pads PD, and a driving chip DIC in the peripheral region NAA. In one or more embodiments, the driving chip DIC may be a data driver.

The display panel DP may include a plurality of pixels PX, a plurality of scan lines SL1 to SLm, a plurality of data lines DL1 to DLn, a plurality of emission lines EL1 to ELm, first and second control lines CSLI1 and CSL2, a power line PL, and a plurality of display pads PD. Here, m and n are natural numbers. The pixels PX may be connected to the scan lines SL1 to SLm, the data lines DL1 to DLn, and the emission lines EL1 to ELm.

The scan lines SL1 to SLm may extend in the first direction DR1 and may be connected to the scan driver SDV. The data lines DL1 to DLn in the first region A1 may extend in the second direction DR2 and may be connected to the driving chip DIC arranged in the second region A2 as shown, for example, in FIG. 5. However, the present disclosure is not limited thereto, and the driving chip DIC may be located in the third region A3 and may be connected to the data lines DL1 to DLn in the first region A1 via the second region A2 (see, e.g., FIG. 2). The emission lines EL1 to ELm may extend in the first direction DR1 and may be connected to the emission driver EDV.

The power line PL may include a portion extending in the first direction DR1 and a portion extending in the second direction DR2. The portion extending in the first direction DR1 and the portion extending in the second direction DR2 may be arranged on different layers. The portion, of the power line PL extending in the second direction DR2 may extend to the third region A3 via the second region A2 from the first region A1. The power line PL may provide a reference voltage to the pixels PX.

The first control line CSL1 may be connected to the scan driver SDV and may extend from the first region A1 to the third region A3 via the second region A2. The second control line CSL2 may be connected to the emission driver EDV and may extend from the first region A1 to the third region A3 via the second region A2.

The display pads PD may be arranged in a display pad region PDA. The display pads PD may be arranged to be adjacent to an end of the third region A3 in the second direction DR2. The driving chip DIC, the power line PL, the first control line CSL1, and the second control line CSL2 may be connected to the display pads PD. A flexible circuit film FCB may overlap the end of the third region A3 of the display panel DP and may be arranged on the display panel DP. Board pads FD may be arranged in a board pad region FDA of the flexible circuit film FCB. The board pads FD may overlap the display pads PD in one-to-one manner. The board pads FD may be electrically connected to the display pads PD through an anisotropic conductive film (ACF) or a non-conductive film (NCF), which will be described in more detail later.

According to one or more embodiments, the display pads PD and the board pads FD may be arranged to be spaced and/or apart (e.g., spaced apart or separated) along the first direction DR1 and the second direction DR2. FIG. 5 illustrates that the display pads PD and the board pads FD each are arranged in three rows, but the number of display pads PD, the number of board pads FD, and an arrangement of the display pads PD and the board pads FD are not limited to any one embodiment.

According to one or more embodiments, pad lines PD-L connecting the driving chip DIC and the display pads PD may be further included. The pad lines PD-L may extend from the active region AA to the display pad region PDA via the second region A2. The pad lines PD-L connecting the driving chip DIC and the display pads PD are not limited to any one embodiment as long as a pad line PD-L is a line connected to a pad.

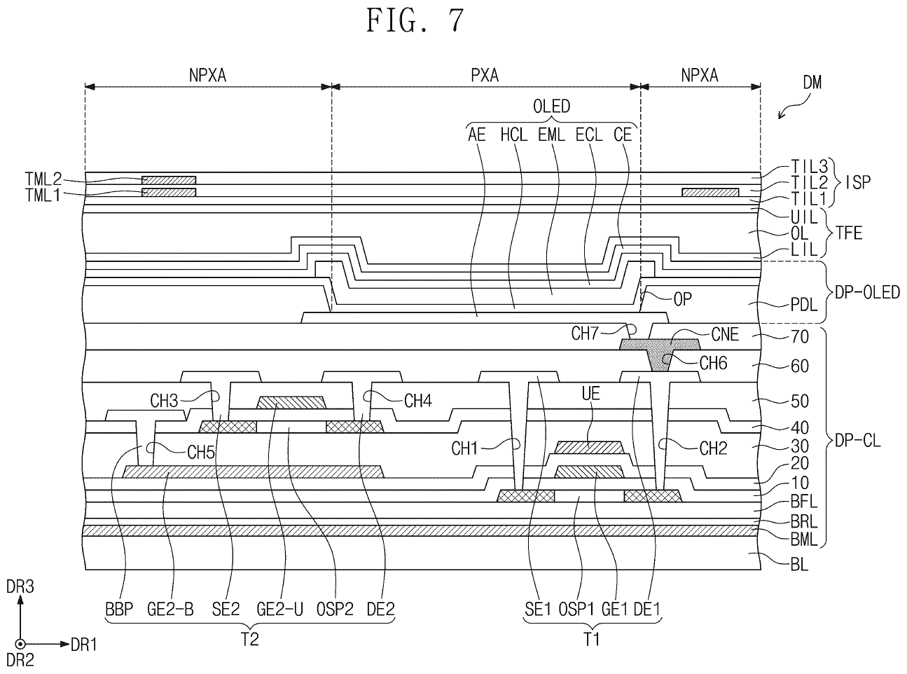

The display panel DP according to one or more embodiments may include a first contact hole CN-H1 defined in the first region A1. The display panel DP may include extension trace lines TL-L. The extension trace lines TL-L may extend to the third region A3 via the first region A1 and the second region A2. The extension trace lines TL-L may be connected, through the first contact hole CN-H1 and in one-to-one manner, to corresponding trace lines among trace lines TL1, TL2, and TL3 (see, e.g., FIG. 6), to be described in more detail later. For example, one end of each of the extension trace lines TL-L may be exposed from the first contact hole CN-H1 and may be connected to the trace lines TL1, TL2, and TL3 (see, e.g., FIG. 6), and the other end of each of the extension trace lines TL-L may be connected to the display pads PD.

FIG. 5 illustrates that the extension trace lines TL-L are arranged between the data lines DL1 to DLn, but the present disclosure is not limited thereto, and the data lines DL1 to DLn may be arranged between the extension trace lines TL-L. In one or more embodiments, the first contact hole CN-H1 may be provided as a plurality of contact holes with the data lines DL1 to DLn therebetween.

FIG. 6 is a plan view of an input sensor according to one or more embodiments of the present disclosure.

Referring to FIG. 6, an input sensor ISP according to one or more embodiments may include sensing electrodes TE1 and TE2 and trace lines TL1, TL2, and TL3. In embodiments in which the input sensor ISP is directly formed on the display panel DP through a substantially continuous process, the sensing electrodes TE1 and TE2 may be formed in only the active region AA, overlapping the first region A1 of the display panel DP.

The input sensor ISP may obtain information about an external input through a change in capacitance between first sensing electrodes TE1 and second sensing electrodes TE2. The first sensing electrodes TE1 are arranged along the first direction DR1 and each extend along the second direction DR2. The first sensing electrodes TE1 may each include first sensing patterns SP1 and first connection patterns CP1.

The first sensing patterns SP1 are arranged in the active region AA. The first sensing patterns SP1 included in one first sensing electrode TE1 may be arranged along the second direction DR2. The first sensing patterns SP1 may have a rhombic shape. However, this is illustrated as an example, and the first sensing patterns SP1 may have one or more suitable shapes and is not limited to any one embodiment.

The first connection pattern CP1 is arranged in the active region AA. The first connection pattern CP1 may be arranged between the first sensing patterns SP1 adjacent along the second direction DR2. The first connection pattern CP1 and the first sensing pattern SP1 may be arranged on different layers and may be connected through a contact hole.

The second sensing electrodes TE2 are arranged along the second direction DR2 and each extend along the first direction DR1. The second sensing electrodes TE2 may each include second sensing patterns SP2 and second connection patterns CP2.

The second sensing patterns SP2 may be spaced and/or apart (e.g., spaced apart or separated) from the first sensing patterns SP1. The first sensing patterns SP1 and the second sensing patterns SP2 may be to transmit and receive independent electrical signals without being in contact with each other.

The second sensing patterns SP2 are arranged in the active region AA. The second sensing patterns SP2 included in one second sensing electrode TE2 may be arranged along the first direction DR1. The second sensing patterns SP2 may have the same shape as the first sensing pattern SP1. For example, the second sensing patterns SP2 may have a rhombic shape. However, this is illustrated as an example, and the second sensing patterns SP2 may have one or more suitable shapes and is not limited to any one embodiment.

The second connection pattern CP2 may be arranged between adjacent second sensing patterns SP2. The second sensing patterns SP2 and the second connection patterns CP2 that are substantially included in one second sensing electrode TE2 may be formed in an integrated shape or as an integrated pattern.

According to one or more embodiments, the first sensing patterns SP1, the second sensing patterns SP2, and the second connection patterns CP2 may be arranged on the same layer, and the first connection patterns CP1 may be arranged on a different layer. The first sensing patterns SP1, the second sensing patterns SP2, and the second connection patterns CP2 may be provided as a plurality of mesh lines extending in a diagonal direction of each of the first direction DR1 and the second direction DR2.

The trace lines TL1, TL2, and TL3 are arranged in the peripheral region NAA. The trace lines TL1, TL2, and TL3 may include first trace lines TL1, second trace lines TL2, and third trace lines TL3.

In one or more embodiments, each first sensing electrode TE1 may be connected to a first trace line TL1 at one end and a second trace line TL2 at the other, opposite end along the second direction DR2. For example, one end of each of the first trace lines TL1 may be connected to a respective one of the first sensing electrodes TE1. In one or more embodiments, each of the first trace lines TL1 is connected to a lower end among the two ends of each of the first sensing electrodes TE1. One end of each of the second trace lines TL2 is connected to an upper end among the two ends of each of the first sensing electrodes TE1. According to embodiments of the present disclosure, one first sensing electrode TE1 may be connected to both the first trace line TL1 and the second trace line TL2. Accordingly, the first sensing electrodes TE1 having a relatively great length compared to the second sensing electrodes TE2 may be able to uniformly (e.g., substantially uniformly) maintain region-dependent sensitivity.

However, this is illustrated as an example, and in the input sensor ISP according to one or more embodiments of the present disclosure, any one of the first trace lines TL1 or the second trace lines TL2 may not be provided, and the present disclosure is not limited to any one embodiment.

In one or more embodiments, each second sensing electrode TE2 may be connected to a third trace line TL3. For example, one end of each of the third trace lines TL3 may be connected to a respective one of the second sensing electrodes TE2. In one or more embodiments, the third trace lines TL3 are connected to a left end among two ends of each of the second sensing electrodes TE2 along the first direction DR1.

A second contact hole CN-H2, which is defined by penetrating at least one of insulating layers included in the input sensor ISP, may be defined in the input sensor ISP. The second contact hole CN-H2 may overlap the first contact hole CN-H1 defined in the first region A1 of the display panel DP.

The other end of each of the trace lines TL1, TL2, and TL3 may be arranged in the second contact hole CN-H2. The other end of each of the trace lines TL1, TL2, and TL3 arranged in the second contact hole CN-H2 may be connected to a respective one of the extension trace lines TL-L (see, e.g., FIG. 5). The trace lines TL1, TL2, and TL3 may be connected to the pads PD (see, e.g., FIG. 5) through the extension trace lines TL-L arranged in the display panel DP (see, e.g., FIG. 5).

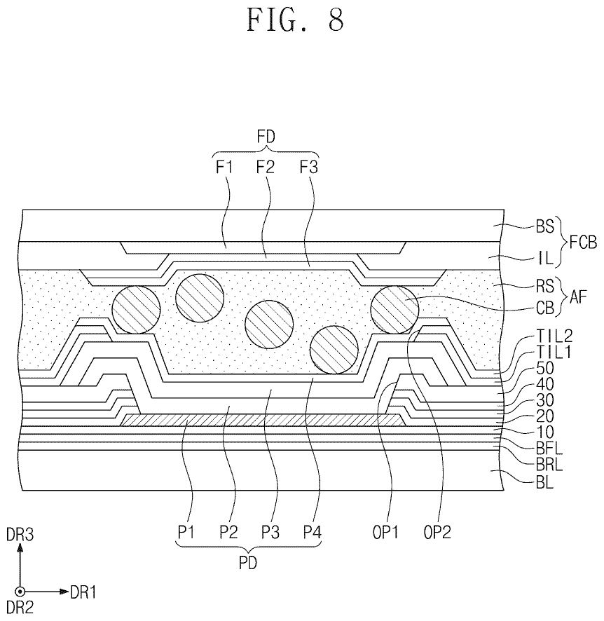

FIG. 7 is a cross-sectional view of a display module according to one or more embodiments of the present disclosure.

FIG. 7 illustrates a cross section corresponding to a first transistor T1, a second transistor T2, and a light-emitting element OLED as a partial configuration of the pixel PX (see, e.g., FIG. 5). While FIG. 7 illustrates one light-emitting element OLED and its associated circuitry, structures, and arrangement, the remaining light-emitting elements of the display panel DP may have the same or similar configuration as described with reference to the embodiments of FIG. 7.

The display panel DP may include a base substrate BL, a circuit element layer DP-CL arranged on the base substrate BL, a display element layer DP-OLED, and an encapsulation layer TFE. The display panel DP may further include functional layers such as an anti-reflective layer and a refractive index adjusting layer. The circuit element layer DP-CL includes at least a plurality of insulating layers and a circuit element. Hereinafter, the insulating layers may include an organic layer and/or an inorganic layer.

The circuit element includes a signal line, a pixel driving circuit, and/or the like. The circuit element layer DP-CL may be formed through a process of forming an insulating layer, a semiconductor layer, and a conductive layer through coating, deposition, and/or the like and a process of patterning the insulating layer, the semiconductor layer, and the conductive layer through a photolithography process. The display element layer DP-OLED may include the light-emitting element OLED and a pixel-defining film PDL.

The base substrate BL may include a synthetic resin layer. The synthetic resin layer may include a thermosetting resin. For example, the synthetic resin layer may be a polyimide-based resin layer, and a material thereof is not particularly limited. The synthetic resin layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin. In one or more embodiments, the base substrate BL may include a glass substrate, a metal substrate, an organic/inorganic composite material substrate, and/or the like.

The base substrate BL according to one or more embodiments may include a first base layer, a first cover layer, a second base layer, and a second cover layer which are sequentially stacked along the third direction DR3. The first base layer and the second base layer may include an organic material, and the first cover layer and the second cover layer may include an inorganic material.

A light blocking pattern BML may be arranged on the base substrate BL. The light blocking pattern BML may block or reduce electrical potential caused by a polarization phenomenon from affecting the first transistor T1. In one or more embodiments, the light blocking pattern BML may block or reduce external light from reaching the first transistor T1. In one or more embodiments of the present disclosure, the light blocking pattern BML may be a floating electrode isolated from another electrode or line. The light blocking pattern BML may include molybdenum. According to one or more embodiments, the light blocking pattern BML may not be provided.

A barrier layer BRL may be arranged on the light blocking pattern BML. The barrier layer BRL prevents or reduces the likelihood of (e.g., protects from) foreign substances being introduced from the outside. The barrier layer BRL may include a silicon oxide layer and a silicon nitride layer. Each of the silicon oxide layer and the silicon nitride layer may be provided in plurality, and the silicon oxide layers and the silicon nitride layers may be alternately stacked.

A buffer layer BFL may be arranged on the barrier layer BRL. The buffer layer BFL may improve a bonding force between the base substrate BL and the conductive patterns or semiconductor patterns. The buffer layer BFL may include a silicon oxide layer and a silicon nitride layer. The silicon oxide layer and the silicon nitride layer may be alternately stacked.

A first semiconductor pattern OSP1 is arranged on the buffer layer BFL. The first semiconductor pattern OSP1 may include a silicon semiconductor. The first semiconductor pattern OSP1 may be a polysilicon semiconductor. However, the present disclosure is not limited thereto, and the first semiconductor pattern OSP1 may include amorphous silicon.

The first semiconductor pattern OSP1 may include an input region (or a first portion), an output region (or a second portion), and a channel region (or a third portion), which is between the input region and the output region. The channel region of the first semiconductor pattern OSP1 may be defined in correspondence to a first control electrode GE1 to be described in more detail later. The input region and the output region are doped with a dopant and have relatively high conductivity compared to the channel region. The input region and the output region may be doped with an n-type (kind) dopant. In one or more embodiments, an n-type (kind) first transistor T1 is described as an example, but the first transistor T1 may be a p-type (kind) transistor.

A first insulating layer 10 is arranged on the buffer layer BFL. The first insulating layer 10 overlaps the plurality of pixels PX (see, e.g., FIG. 2) in common (e.g., overlaps all of the pixels PX as one common and continuous layer) and covers the first semiconductor pattern OSP1. The first insulating layer 10 may be an inorganic layer and/or an organic layer and may have a single-layer or multi-layered structure. The first insulating layer 10 may include at least one of aluminum oxide, titanium oxide, silicon oxide, silicon oxynitride, zirconium oxide, or hafnium oxide. In one or more embodiments, the first insulating layer 10 may be a single-layer silicon oxide layer.

A first control electrode GE1 is arranged on the first insulating layer 10. The first control electrode GE1 may overlap the channel region of the first semiconductor pattern OSP1.

A second insulating layer 20 covering the first control electrode GE1 is arranged on the first insulating layer 10. The second insulating layer 20 overlaps the plurality of pixels PX (see, e.g., FIG. 1) in common (e.g., overlaps all of the pixels PX as one common and continuous layer). The second insulating layer 20 may be an inorganic layer and/or an organic layer and may have a single-layer or multi-layered structure. The second insulating layer 20 may include at least one of aluminum oxide, titanium oxide, silicon oxide, silicon oxynitride, zirconium oxide, or hafnium oxide. In one or more embodiments, the second insulating layer 20 may be a single-layer silicon oxide layer.

An upper electrode UE may be further arranged on the second insulating layer 20. The upper electrode UE may overlap the first control electrode GE1.

A lower control electrode GE2-B of the second transistor T2 may be further arranged on the second insulating layer 20. The lower control electrode GE2-B may overlap a second semiconductor pattern OSP2. The lower control electrode GE2-B may form a double gate with an upper control electrode GE2-U.

A third insulating layer 30 covering the upper electrode UE and the lower control electrode GE2-B may be arranged on the second insulating layer 20. The third insulating layer 30 may be an inorganic layer and/or an organic layer and may have a single-layer or multi-layered structure. The third insulating layer 30 may include at least one of aluminum oxide, titanium oxide, silicon oxide, silicon oxynitride, zirconium oxide, or hafnium oxide. In one or more embodiments, the third insulating layer 30 may be a single-layer silicon oxide layer.

The second semiconductor pattern OSP2 may be arranged on the third insulating layer 30. The second semiconductor pattern OSP2 may include oxide semiconductor. The second semiconductor pattern OSP2 may include a crystalline or amorphous oxide semiconductor. For example, the oxide semiconductor may include a metal oxide of zinc (Zn), indium (In), gallium (Ga), tin (Sn), titanium (Ti), and/or the like, and/or a (e.g., any suitable) mixture of metal such as zinc (Zn), indium (In), gallium (Ga), tin (Sn), titanium (Ti), and/or the like, and/or an oxide thereof. The oxide semiconductor may include indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), zinc-tin oxide (ZTO), and/or the like.

The second semiconductor pattern OSP2 may include an input region (or a first portion), an output region (or a second portion), and a channel region (or a third portion), which is between the input region and the output region. Impurities may be included (doped) in the input region and the output region. The channel region of the second semiconductor pattern OSP2 may be defined in correspondence to the upper control electrode GE2-U to be described in more detail later.

Impurities of the second semiconductor pattern OSP2 may be reduced metal materials. The input region and the output region may include metal materials which are reduced from a metal oxide (or metal oxides) constituting the channel region. Accordingly, the second transistor T2 may lower leakage current, and thus may function as a switching element having improved on-off characteristics.

A fourth insulating layer 40 covering the second semiconductor pattern OSP2 may be arranged on the third insulating layer 30. The fourth insulating layer 40 may be an inorganic layer and/or an organic layer and may have a single-layer or multi-layered structure. The fourth insulating layer 40 may include at least one of aluminum oxide, titanium oxide, silicon oxide, silicon oxynitride, zirconium oxide, or hafnium oxide.

The upper control electrode GE2-U may be arranged on the fourth insulating layer 40. The upper control electrode GE2-U overlaps the second semiconductor pattern OSP2.

A fifth insulating layer 50 covering the upper control electrode GE2-U may be arranged on the fourth insulating layer 40. The fifth insulating layer 50 may be an inorganic layer and/or an organic layer and may have a single-layered or multi-layered structure. The fifth insulating layer 50 may include at least one of aluminum oxide, titanium oxide, silicon oxide, silicon oxynitride, zirconium oxide, or hafnium oxide.

A first input electrode SE1, a first output electrode DE1, a second input electrode SE2, and a second output electrode DE2 are arranged on the fifth insulating layer 50. The first input electrode SE1 and the first output electrode DE1 are connected to the first semiconductor pattern OSP1 through a first contact hole CH1 and a second contact hole CH2, respectively, which expose the input region and the output region of the first semiconductor pattern OSP1. The first contact hole CH1 and the second contact hole CH2 penetrate the first insulating layer 10 to the fifth insulating layer 50.

The second input electrode SE2 and the second output electrode DE2 are connected to the second semiconductor pattern OSP2 through a third contact hole CH3 and a fourth contact hole CH4, respectively, which expose the input region and the output region of the second semiconductor pattern OSP2. The third contact hole CH3 and the fourth contact hole CH4 penetrate the fifth insulating layer 50.

The display panel DP according to one or more embodiments may further include a control bridge pattern BBP arranged on the fourth insulating layer 40. The control bridge pattern BBP may branch from a portion of the upper control electrode GE2-U. The control bridge pattern BBP may be connected to the lower control electrode GE2-B through a fifth contact hole CH5. The fifth contact hole CH5 penetrates the third insulating layer 30 and the fourth insulating layer 40.

A sixth insulating layer 60 covering the first input electrode SE1, the first output electrode DE1, the second input electrode SE2, and the second output electrode DE2 is arranged on the fifth insulating layer 50. The sixth insulating layer 60 may be an organic layer and may have a single-layer or multi-layered structure.

A connection electrode CNE is arranged on the sixth insulating layer 60. The connection electrode CNE may be connected to the first output electrode DE1 through a sixth contact hole CH6 penetrating the sixth insulating layer 60.

A seventh insulating layer 70 (or a passivation layer) covering the connection electrode CNE is arranged on the sixth insulating layer 60. The seventh insulating layer 70 may be an organic layer and may have a single-layer or multi-layered structure.

In one or more embodiments, the sixth insulating layer 60 and the seventh insulating layer 70 may be a single-layer polyimide-based resin layer. However, the present disclosure is not limited thereto, and the sixth insulating layer 60 and the seventh insulating layer 70 may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin.

The light-emitting element OLED is arranged on the seventh insulating layer 70. An anode AE of the light-emitting element OLED is arranged on the seventh insulating layer 70. The anode AE is connected to the connection electrode CNE through a seventh contact hole CH7 penetrating the seventh insulating layer 70. The pixel-defining film PDL is arranged on the seventh insulating layer 70.

An opening OP (e.g., plurality of openings OP) of the pixel-defining film PDL exposes at least a portion of the anode AE. Each of the openings OP of the pixel-defining film PDL may define a light-emitting region PXA of a pixel PX. For example, the plurality of pixels PX (see, e.g., FIG. 2) may be arranged in accordance with a certain rule on a plane (e.g., in a plan view) of the display panel DP. A region in which the plurality of pixels PX are arranged may correspond to the active region AA described with reference to FIG. 5, and the active region AA may include light-emitting regions PXA and a non-light-emitting region NPXA adjacent to the light-emitting regions PXA. The non-light-emitting region NPXA may be around (e.g., surround) the light-emitting regions PXA.

A hole control layer HCL may be arranged in the light-emitting regions PXA and the non-light-emitting region NPXA in common (e.g., may be arranged as one common and continuous layer throughout the light-emitting regions PXA and the non-light-emitting region NPXA). A common layer such as the hole control layer HCL may be formed in the plurality of pixels PX (see, e.g., FIG. 2) in common. The hole control layer HCL may include a hole transport layer and a hole injection layer.

An organic emission layer EML is arranged on the hole control layer HCL. The organic emission layer EML may be arranged in only a region corresponding to each of the openings OP. The organic emission layer EML may be separately formed in each of the plurality of pixels PX (see, e.g., FIG. 2).

In one or more embodiments, a patterned organic emission layer EML is illustrated as an example, but the organic emission layer EML may be arranged in the plurality of pixels PX in common (e.g., may be arranged as one common and continuous layer throughout the light-emitting regions PXA and the non-light-emitting region NPXA). In such embodiments, the organic emission layer EML may generate white light. In one or more embodiments, the organic emission layer EML may have a multi-layered structure.

An electron control layer ECL may be arranged on the organic emission layer EML. The electron control layer ECL may include an electron transport layer and an electron injection layer. A cathode CE may be arranged on the electron control layer ECL. The electron control layer ECL and the cathode CE may be arranged in the plurality of pixels PX (see, e.g., FIG. 2) in common (e.g., may each be arranged as one common and continuous layer throughout the light-emitting regions PXA and the non-light-emitting region NPXA).

The encapsulation layer TFE may be arranged on the cathode CE. The encapsulation layer TFE may be arranged in the plurality of pixels PX in common (e.g., may be arranged as one common and continuous layer throughout the light-emitting regions PXA and the non-light-emitting region NPXA). In one or more embodiments, the encapsulation layer TFE directly covers the cathode CE. The encapsulation layer TFE may cover the light-emitting elements OLED. The encapsulation layer TFE may include two inorganic encapsulation layers LIL and UIL and an organic encapsulation layer OL arranged therebetween. In one or more embodiments of the present disclosure, the encapsulation layer TFE may include a plurality of inorganic layers and a plurality of organic layers which are alternately stacked.

The inorganic encapsulation layers LIL and UIL protect the light-emitting element OLED from moisture/oxygen, and the organic encapsulation layer OL protects the light-emitting element OLED from foreign substances such as dust particles. The inorganic encapsulation layers LIL and UIL may include a silicon nitride layer, a silicon oxynitride layer, a silicon oxide layer, a titanium oxide layer, an aluminum oxide layer, and/or the like; however, the present disclosure is not limited thereto. The organic encapsulation layer OL may include an acrylic organic layer; however, the present disclosure is not limited thereto.

According to one or more embodiments, the first transistor T1 may include silicon semiconductor, for example, a polysilicon semiconductor, and may thus have high electron mobility. Because the second transistor T2 includes an oxide semiconductor, leakage current may be reduced. Thus, a driving voltage of the pixel PX (see, e.g., FIG. 2) may be reduced, and malfunction of the pixel PX (see, e.g., FIG. 2) may be prevented or reduced.

An input sensor ISP may be directly arranged on the display panel DP. The input sensor ISP may include sensing insulating layers TIL1, TIL2, and TIL3 and one or more conductive layers TML1 and TML2. The sensing insulating layers TIL1, TIL2, and TIL3 may include an inorganic material and/or an organic material.

A first sensing insulating layer TIL1 may be directly arranged on a second inorganic layer UIL of the encapsulation layer TFE. A first conductive layer TML1 may be arranged on the first sensing insulating layer TIL1. A second sensing insulating layer TIL2 may be arranged on the first sensing insulating layer TIL1 and may cover the first conductive layer TML1. A second conductive layer TML2 may be arranged on the second sensing insulating layer TIL2. A third sensing insulating layer TIL3 may be arranged on the second sensing insulating layer TIL2 and may cover the second conductive layer TML2. However, the present disclosure is not limited thereto, and the first sensing insulating layer TIL1 may not be provided, and the first conductive layer TML1 may be directly arranged on the second inorganic layer UIL, and the present disclosure is not limited to any one embodiment.

According to the present disclosure, the first and second sensing insulating layers TIL1 and TIL2 may include an inorganic material, and the third sensing insulating layer TIL3 may include an organic material.

The first connection patterns CP1 of the sensing electrodes TE1 and TE2, described with reference to FIG. 6, may be included in the first conductive layer TML1. The first sensing patterns SP1, the second sensing patterns SP2, and the second connection patterns CP2 may be included in the second conductive layer TML2. Thus, adjacent first sensing patterns SP1 may be connected to the first connection pattern CP1 through a contact hole which is defined in the second sensing insulating layer TIL2.

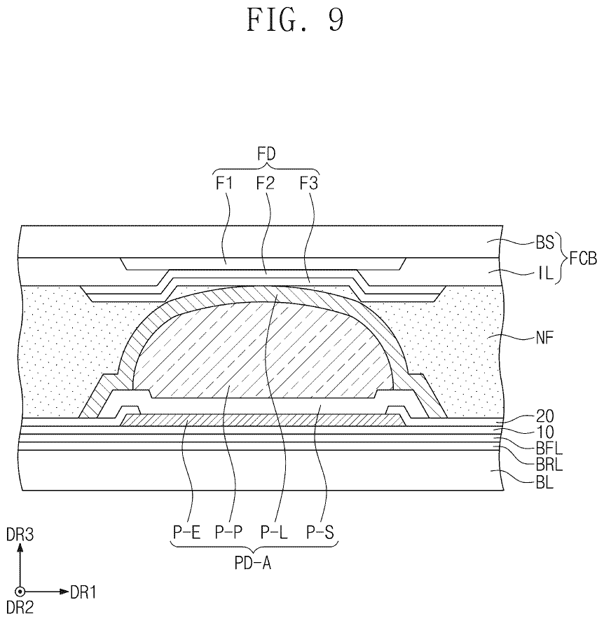

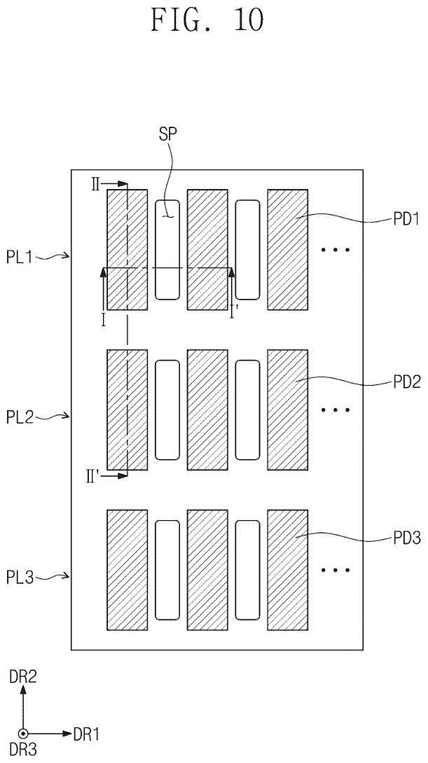

FIG. 8 is a cross-sectional view of pads coupled to each other according to one or more embodiments of the present disclosure. FIG. 9 is a cross-sectional view of pads coupled to each other according to one or more embodiments of the present disclosure. Descriptions of display pads PD and PD-A made with reference to FIGS. 8 and 9 may be applied to display pads to be described in more detail later, and duplicate description may not be provided.

Referring to FIG. 8, the display pad DP according to one or more embodiments may be coupled to a board pad FD through a film layer AF. The film layer AF according to one or more embodiments may include a conductive ball CB (e.g., a plurality of conductive balls) and a resin layer RS. The resin layer RS may include a resin. In one or more embodiments, the film layer AF may be provided as an anisotropic conductive film (ACF).

The display pad PD according to one or more embodiments may include first to fourth patterns P1, P2, P3, and P4. The first pattern P1 may be arranged on the first insulating layer 10. The first pattern P1 may be formed through the same process as that for the first semiconductor pattern OSP1 described with reference to FIG. 7. Thus, the first pattern P1 may include the same material as the first semiconductor pattern OSP1.

The second pattern P2 may be arranged on the first pattern P1. The second pattern P2 may be arranged in a first opening OP1 in which second to fifth insulating layers 20, 30, 40 and 50 are penetrated. For example, the second to fifth insulating layers 20, 30, 40 and 50 may define the first opening OP1 in which the second pattern P2 is located. The second pattern P2 may be formed through the same process as that for the input/output electrodes SE1, SE2, DE1, and DE2. Thus, the second pattern P2 may include the same material as the input/output electrodes SE1, SE2, DE1, and DE2.

The third pattern P3 may be arranged on the second pattern P2. The third pattern P3 may be formed through the same process as that for the connection electrode CNE. Thus, the third pattern P3 may include the same material as the connection electrode CNE.

The fourth pattern P4 may be arranged on the third pattern P3. The fourth pattern P4 may be arranged in a second opening OP2 in which the first and second sensing insulating layers TIL1 and TIL2 are penetrated. For example, the first and second sensing insulating layers TIL1 and TIL2 may define the second opening OP2 in which the fourth pattern P4 is located. The fourth pattern P4 may be formed through the same process as that for the second conductive layer TML2 of the input sensor ISP described with reference to FIG. 7. Thus, the fourth pattern P4 may include the same material as the second conductive layer TML2. However, the present disclosure is not limited thereto, and the fourth pattern P4 may be formed through the same process as that for the first conductive layer TML1.

According to one or more embodiments, at least one of the first to fourth patterns P1, P2, P3, or P4 included in the display pad PD may not be provided, and the present disclosure is not limited to any one embodiment.

A flexible circuit film FCB according to one or more embodiments may include a base film BS, an insulating layer IL, and the board pad FD. The board pad FD may include first to third pad layers F1, F2, and F3. The base film BS may include silicon.

The first pad layer F1 may be arranged under the base film BS. The first pad layer F1 may include aluminum (Al). The insulating layer IL may be arranged under the base film BS and have an opening, which exposes at least a portion of the first pad layer F1. The second pad layer F2 may be arranged under the first pad layer F1. The second pad layer F2 may include an under bump metallization (UBM) material. The third pad layer F3 may be arranged under the second pad layer F2. The third pad layer F3 may include gold (Au). The third pad layer F3 may be connected to the fourth pattern P4 through the conductive balls CB.

According to one or more embodiments of the present disclosure, the board pad FD may have a structure in which a bump arranged under the third pad layer F3 is omitted. Thus, a thickness of the resin layer RS may be reduced by as much as a thickness of the bump, and accordingly, a slim display device may be provided. However, because an area in which the resin layer RS is in contact with pads is reduced due to the lack of a bump, adhesive force between the pads may be reduced, and mechanical strength in the pad regions PDA and FDA (see, e.g., FIG. 7) may be reduced. Thus, a structure in which a contact area of the resin layer RS may be increased in a bumpless structure may be desired or required.

Referring to FIG. 9, the display pad PD-A according to one or more embodiments may be coupled to a board pad FD through a film layer NF. The film layer NF according to one or more embodiments may include only a resin. Thus, as in FIG. 9, the conductive balls CB may not be provided or included in the film layer NF. In one or more embodiments, the film layer NF may be provided as a non-conductive film (NCF).

The display pad PD-A according to one or more embodiments may include a wiring pattern P-E, a first conductive pattern P-S, an insulating pattern P-P, and a second conductive pattern P-L. The wiring pattern P-E may be arranged on a first insulating layer 10. The wiring pattern P-E may be a portion of the data lines DL1 to DLn arranged in the peripheral region NAA or a portion of the pad lines PD-L described with reference to FIG. 5.

The first conductive pattern P-S may be connected to the wiring pattern P-E through an opening penetrating the second insulating layer 20. The first conductive pattern P-S may include first to third layers which are sequentially stacked. The first and third layers may include titanium, and the second layer may include aluminum.

The insulating pattern P-P may be arranged on the first conductive pattern P-S. The insulating pattern P-P may have a convex shape protruding along the third direction DR3 before being compressed against the board pad FD. The insulating pattern P-P may include a polymer. The insulating pattern P-P according to one or more embodiments may include negative photoresist (PR) or positive photoresist (PR).

The second conductive pattern P-L may cover the insulating pattern P-P. The second conductive pattern P-L may include first to third layers which are sequentially stacked. The first and third layers may include titanium, and the second layer may include aluminum. Two ends of the second conductive pattern P-L may be in contact with the first conductive pattern P-S. A flexible circuit film FCB is the same as that described with reference to FIG. 8, and duplicate description may not be provided.

According to one or more embodiments, the second conductive pattern P-L may be in direct contact with the board pad FD in a process of compressing the display pad PD-A and the board pad FD.

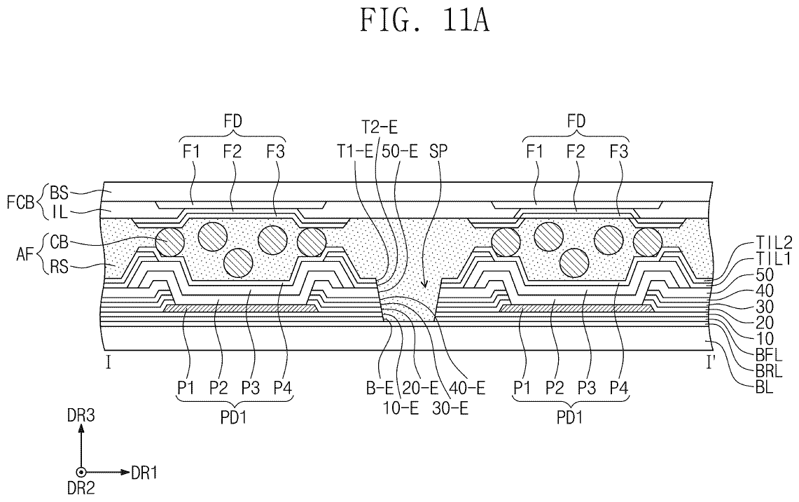

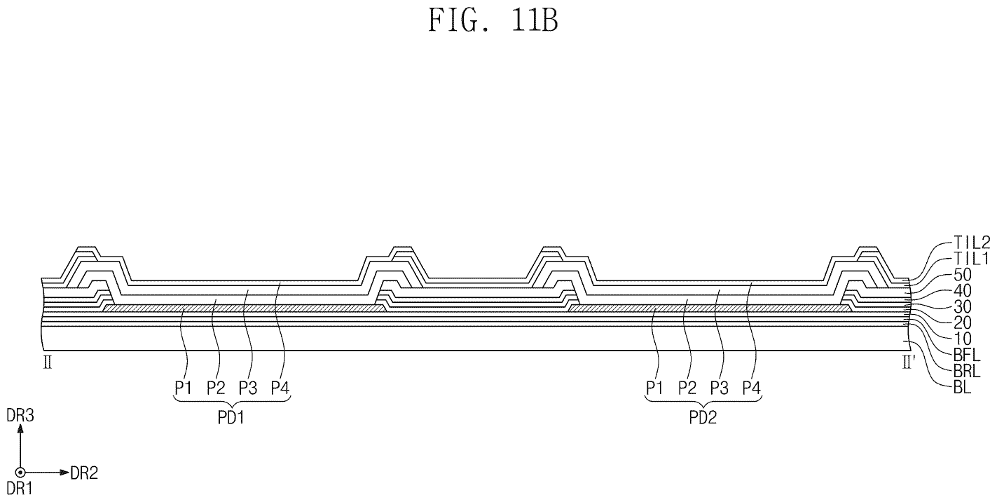

FIG. 10 is a plan view of a portion of a display pad region according to one or more embodiments of the present disclosure. FIG. 11A is a cross-sectional view taken along the line I-I′ of FIG. 10, according to one or more embodiments of the present disclosure. FIG. 11B is a cross-sectional view taken along the line II-II′ of FIG. 10, according to one or more embodiments of the present disclosure. A component that is the same as and/or similar to the component described with reference to FIGS. 5 to 9 may be denoted with the same and/or similar reference numerals or symbols, respectively, and duplicate descriptions may not be provided. FIG. 10 illustrates a portion of the display pads PD included in the display pad region PDA described, for example, with reference to FIG. 5. FIG. 11A illustrates board pads FD of the flexible circuit film FCB described, for example, with reference to FIG. 8.

Referring to FIGS. 10 to 11B, board pads PD1, PD2, and PD3 according to one or more embodiments may be arranged to be spaced and/or apart (e.g., spaced apart or separated) along the first direction DR1 and the second direction DR2. The board pads PD1, PD2, and PD3 may each extend along the second direction DR2. In one or more embodiments, first pads PD1 arranged along the first direction DR1 may be defined as a first pad row PL1, second pads PD2 arranged along the first direction DR1 may be defined as a second pad row PL2, and third pads PD3 arranged along the first direction DR1 may be defined as a third pad row PL3. The first to third row pads PL1, PL2, and PL3 may be spaced and/or apart (e.g., spaced apart or separated) along the second direction DR2.

The display panel DP (see, e.g., FIG. 5) according to embodiments of the present disclosure may include a groove SP. The groove SP may be provided in plurality in the display pad region PDA (see, e.g., FIG. 5).

The grooves SP may be arranged to be spaced and/or apart (e.g., spaced apart or separated) along the first direction DR1 and the second direction DR2. The grooves SP may extend along the second direction DR2.

According to one or more embodiments, the grooves SP arranged along the first direction DR1 may be defined between pads arranged in the same row pad. One groove SP may be arranged between adjacent first pads PD1 among the first pads PD1 included in the first pad row PL1 along the first direction DR1. For example, a groove SP may be positioned between each pair of adjacent first pads PD1 included in the first pad row PL1, resulting in an alternating pattern of first pads PD1 and grooves SP in the first direction DR1 for the first pad row PL1.

Another groove SP spaced and/or apart (e.g., spaced apart or separated) from the one groove SP along the second direction DR2 may be arranged between adjacent second pads PD2 among the second pads PD2 included in the second pad row PL2 along the first direction DR1. For example, a groove SP may be positioned between each pair of adjacent second pads PD2 included in the second pad row PL2, resulting in an alternating pattern of second pads PD2 and grooves SP in the first direction DR1 for the second pad row PL2.

Another groove SP spaced and/or apart (e.g., spaced apart or separated) from the other groove SP along the second direction DR2 may be arranged between adjacent third pads PD3 among the third pads PD3 included in the third pad row PL3 along the first direction DR1. For example, a groove SP may be positioned between each pair of adjacent third pads PD3 included in the third pad row PL3, resulting in an alternating pattern of third pads PD3 and grooves SP in the first direction DR1 for the third pad row PL3.

Referring to FIGS. 11A and 11B, the groove SP may be defined by penetrating insulating layers arranged on the base substrate BL. According to one or more embodiments, the groove SP may be formed by penetrating insulating layers arranged on the barrier layer BRL. More specifically, the groove SP may be formed by penetrating the buffer layer BFL, first to fifth insulating layers 10, 20, 30, 40, and 50, and first and second sensing insulating layers TIL1 and TIL2, which are arranged on the barrier layer BRL. For example, the sidewalls of the groove SP may be defined by end surfaces of the buffer layer BFL, the end surfaces of the first to fifth insulating layers 10, 20, 30, 40, and 50, and the end surfaces of the first and second sensing insulating layers TIL1 and TIL2 through which the groove has been formed. The barrier layer BRL, the buffer layer BFL, the first to fifth insulating layers 10, 20, 30, 40, and 50, and the first and second sensing insulating layers TIL1 and TIL2 may be the same as those described with reference to FIG. 7.

Thus, the groove SP may be defined by aligning a side surface (e.g., end surface) B-E of the buffer layer BFL, side surfaces (e.g., end surfaces) 10-E, 20-E, 30-E, 40-E, and 50-E of the first to fifth insulating layers 10, 20, 30, 40, and 50, and side surfaces (e.g., end surfaces) T1-E and T2-E of the first and second sensing insulating layers TIL1 and TIL2.

According to one or more embodiments, the side surfaces B-E, 10-E, 20-E, 30-E, 40-E, 50-E, T1-E, and T2-E which define the groove SP may be aligned with each other and may be inclined at a set or predetermined angle from the barrier layer BRL.

According to one or more embodiments of the present disclosure, a portion of the barrier layer BRL exposed by the groove SP may be in direct contact with the resin layer RS included in the film layer AF. In one or more embodiments, the resin layer RS may be arranged inside the groove SP and may be in direct contact with the side surfaces B-E, 10-E, 20-E, 30-E, 40-E, 50-E, T1-E, and T2-E that define the groove SP.

According to one or more embodiments, because the groove SP is included between adjacent display pads PD, a contact area between the resin layer RS included in the film layer AF and the display panel DP (see, e.g., FIG. 7) may be increased. Accordingly, a display device in which mechanical strength of the display panel DP (see, e.g., FIG. 5) in the pad regions PDA and FDA (see, e.g., FIG. 5) is improved may be provided. In one or more embodiments, because a filling amount of the resin layer RS in the pad regions PDA and FDA (see, e.g., FIG. 5) is increased, the display device having improved bonding force between the pads PD and FD may be provided.

As illustrated in FIG. 11B, the groove SP may not be defined between the first pad PD1 and the second pad PD2 that are adjacent to each other along the second direction DR2. The pad lines PD-L described, for example, with reference to FIG. 5 may be arranged between the first pad PD1 and the second pad PD2.

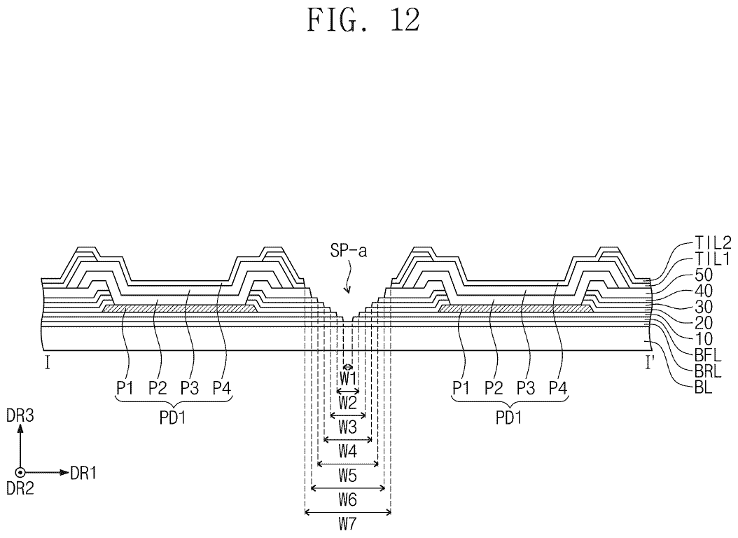

FIG. 12 is a cross-sectional view of pads coupled to (e.g., adjacent to) each other according to one or more embodiments of the present disclosure. A component that is the same as and/or similar to the component described with reference to FIGS. 10 to 11B may be denoted with the same and/or similar reference numerals or symbols, respectively, and duplicate descriptions may not be provided. FIG. 12 is a cross-sectional view taken along the line I-I′ of FIG. 10, according to one or more embodiments of the present disclosure.

A groove SP-a may be defined by penetrating insulating layers arranged on a base substrate BL. According to one or more embodiments, the groove SP-a may be formed by penetrating insulating layers arranged on the barrier layer BRL. The groove SP-a may be formed by penetrating the buffer layer BFL, first to fifth insulating layers 10, 20, 30, 40, and 50, and first and second sensing insulating layers TIL1 and TIL2, which are arranged on the barrier layer BRL. For example, the sidewalls of the groove SP may be defined by end surfaces of the buffer layer BFL, the end surfaces of the first to fifth insulating layers 10, 20, 30, 40, and 50, and the end surfaces of the first and second sensing insulating layers TIL1 and TIL2 through which the groove has been formed.

Thus, the groove SP-a may be defined by the side surface (e.g., end surface) B-E of the buffer layer BFL, the side surfaces (e.g., end surfaces) 10-E, 20-E, 30-E, 40-E, and 50-E of the first to fifth insulating layers 10, 20, 30, 40, and 50, and the side surfaces (e.g., end surfaces) T1-E and T2-E of the first and second sensing insulating layers TIL1 and TIL2.

According to one or more embodiments, the widths (in the first direction DR1) of each of the spaces between the side surfaces B-E, 10-E, 20-E, 30-E, 40-E, 50-E, T1-E, and T2-E which define the groove SP-a may be different from each other. For example, the widths in the first direction DR1 may increase in a direction away from the base substrate BL.

For example, a first width W1 of the space in the buffer layer BFL defining the groove SP-a may be smaller than a second width W2 of the space in the first insulating layer 10, the second width W2 may be smaller than a third width W3 of the space in the second insulating layer 20, the third width W3 may be smaller than a fourth width W4 of the space in the third insulating layer 30, the fourth width W4 may be smaller than a fifth width W5 of the space in the fourth insulating layer 40, the fifth width W5 may be smaller than a sixth width W6 of the space in the fifth insulating layer 50, and the sixth width W6 may be smaller than a seventh width W7 of the space in the first and second sensing insulating layers TIL1 and TIL2.

According to one or more embodiments, because the side surfaces of the insulating layers defining the groove SP-a are patterned in a stair shape, an area in which the resin layer RS (see, e.g., FIG. 8) is in contact with the insulating layers inside the groove SP-a may be increased.

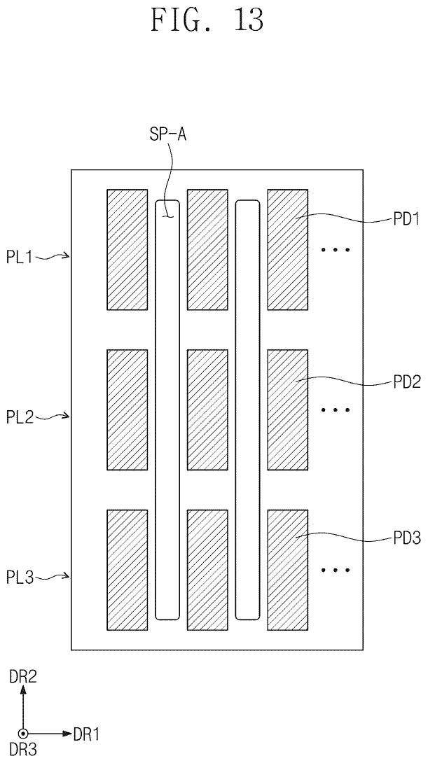

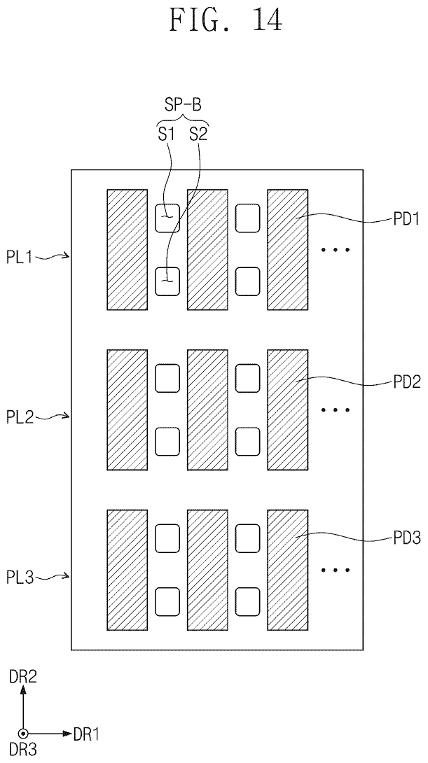

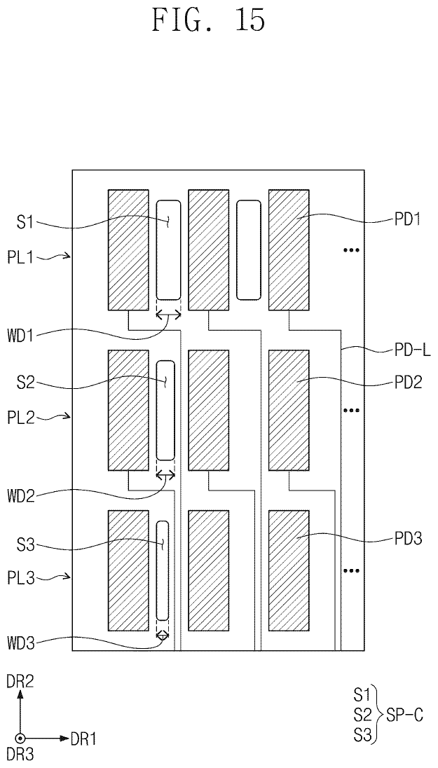

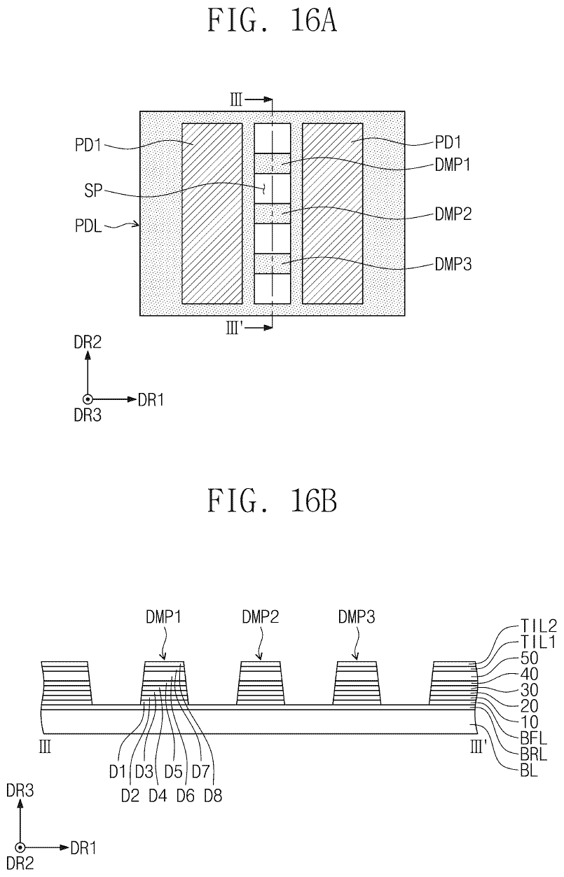

FIG. 13 is a plan view of a portion of a display pad region according to one or more embodiments of the present disclosure. FIG. 14 is a plan view of a portion of a display pad region according to one or more embodiments of the present disclosure. FIG. 15 is a plan view of a portion of a display pad region according to one or more embodiments of the present disclosure. FIG. 16A is a plan view of a portion of a display pad region according to one or more embodiments of the present disclosure. FIG. 16B is a cross-sectional view taken along the line III-III′ of FIG. 16A, according to one or more embodiments of the present disclosure.

A component that is the same as and/or similar to the component described with reference to FIGS. 5 to 11B may be denoted with the same and/or similar reference numerals or symbols, respectively, and duplicate description may not be provided. An arrangement form of display pads illustrated in FIGS. 13 to 15 is substantially the same as the arrangement form of the display pads described with reference to FIG. 10, and duplicate description may not be provided. In addition, a cross-section of a groove described with reference to FIGS. 13 to 15 may correspond or be substantially similar to that described with reference to FIG. 11A, and duplicate description may not be provided.

Referring to FIG. 13, the display panel DP (see, e.g., FIG. 5) according to the present disclosure may include a groove SP-A. The groove SP-A may include a plurality of grooves SP-A in the display pad region PDA (see, e.g., FIG. 5).

The grooves SP-A may be arranged to be spaced and/or apart (e.g., spaced apart or separated) along the first direction DR1. In one or more embodiments, the grooves SP-A may each extend along the second direction DR2.

Thus, the grooves SP-A may overlap pads included in different pad rows and may be arranged along the second direction DR2 when viewed in the first direction DR1.

For example, the groove SP-A may overlap a first pad PD1 included in the first pad row PL1, a second pad PD2 spaced and/or apart (e.g., spaced apart or separated) from the first pad PD1 along the second direction DR2 and included in the second pad row PL2, and a third pad PD3 spaced and/or apart (e.g., spaced apart or separated) from the second pad PD2 along the second direction DR2 and included in the third pad row PL3 when viewed in the first direction DR1.

Referring to FIG. 14, grooves SP-B according to one or more embodiments may each include sub grooves S1 and S2. A cross-section of the sub grooves S1 and S2 taken along the first direction DR1 may correspond to that of FIG. 11A when viewed in the second direction DR2.

The sub grooves S1 and S2 may be arranged along the second direction DR2. The sub grooves S1 and S2 may be arranged between pads arranged in the same pad row and spaced and/or apart (e.g., spaced apart or separated) along the first direction DR1. For example, one groove SP-B may be arranged between two first pads PD1 that are adjacent along the first direction DR1, and the one groove SP-B may include two sub grooves S1 and S2. However, the present disclosure is not limited thereto, and the number of sub grooves arranged in one groove SP-B may be two or more.

Referring to FIG. 15, a groove SP-C according to one or more embodiments may include grooves S1, S2, and S3. First grooves S1 may be arranged between first pads PD1 in the first pad row PL1, second grooves S2 may be arranged between second pads PD2 in the second pad row PL2, and third grooves S3 may be arranged between third pads PD3 in the third pad row PL3. Widths (in the first direction DR1) of the first to third grooves S1, S2, and S3 arranged in different pads rows may be different from each other.

For example, the first groove S1 arranged between the first pads PD1 included in the first pad row PL1 may have a first width WD1 in the first direction DR1. The second groove S2 arranged between the second pads PD2 included in the second pad row PL2 may have a second width WD2 in the first direction DR1. The third groove S3 arranged between the third pads PD3 included in the third pad row PL3 may have a third width WD3 in the first direction DR1.

The second width WD2 may be smaller than the first width WD1 and greater than the third width WD3. According to one or more embodiments, a different number of pad lines PD-L may be arranged between the pads included in different pad rows. The pad lines PD-L may be connected to the transistors T1 and T2 described with reference to FIG. 7 and the display pads.

For example, the number of pad lines PD-L arranged between pads adjacent to a groove having a small width along the first direction DR1 may be greater than the number of pad lines PD-L arranged between pads adjacent to a groove having a relatively large width along the first direction DR1.

For example, the number of pad lines PD-L arranged between the third pads PD3 adjacent to the third groove S3 along the first direction DR1 may be greater than the number of pad lines PD-L arranged between the second pads PD2 adjacent to the second groove S2 along the first direction DR1.

Referring to FIGS. 16A and 16B, the display panel DP (see, e.g., FIG. 5) may include first to third dam patterns DMP1, DMP2, and DMP3. The first to third dam patterns DMP1, DMP2, and DMP3 may be arranged inside one groove SP. The first to third dam patterns DMP1, DMP2, and DMP3 may be arranged to be spaced and/or apart (e.g., spaced apart or separated) along the second direction DR2 in one groove SP.

As illustrated in FIG. 16B, the first to third dam patterns DMP1, DMP2, and DMP3 may each include first to eighth patterns D1 to D8 which are sequentially stacked. The first to eighth patterns D1 to D8 may include the same material as the insulating layers which define the groove SP described, for example, with reference to FIG. 11A.

For example, the first pattern D1 may be formed through substantially the same process and include substantially the same material as the buffer layer BFL, the second pattern D2 may be formed through substantially the same process and include substantially the same material as the first insulting layer 10, the third pattern D3 may be formed through substantially the same process and include substantially the same material as the second insulating layer 20, the fourth pattern D4 may be formed through substantially the same process and include substantially the same material as the third insulating layer 30, the fifth pattern D5 may be formed through substantially the same process and include substantially the same material as the fourth insulating layer 40, the sixth pattern D6 may be formed through substantially the same process and include substantially the same material as the fifth insulating layer 50, the seventh pattern D7 may be formed through substantially the same process and include substantially the same material as the first sensing insulating layer TIL1, and the eighth pattern D8 may be formed through substantially the same process and include substantially the same material as the second sensing insulating layer TIL2. At least any one of the first to eighth patterns D1 to D8 may not be provided.

According to one or more embodiments, because the first to third dam patterns DMP1, DMP2, and DMP3 arranged inside the groove SP are included, a contact area of the resin layer RS described with reference to FIG. 11A may be increased.

According to one or more embodiments of the present disclosure, an area in which a resin arranged between pads of a display panel and pads of a circuit board is in contact with the pads and a region adjacent to the pads may be increased, and thus bonding force between the pads may be improved, and a display device having improved mechanical strength may be provided.

In the present disclosure, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a base substrate having an active region and a peripheral region adjacent to the active region;
a circuit element layer comprising a barrier layer on the base substrate, insulating layers on the barrier layer, and transistors each comprising conductive patterns between the insulating layers;
a display element layer comprising light-emitting elements connected to the transistors;
display pads in the peripheral region and connected to the transistors;
a circuit board comprising board pads coupled to the display pads; and
a film layer between the display pads and the board pads,
wherein side surfaces of the insulating layers define a groove, the groove exposing a portion of the barrier layer and located between adjacent display pads of the display pads, and
the film layer is in contact with the portion of the barrier layer exposed by the groove.

2. The display device of claim 1, wherein the side surfaces of the insulating layers defining the groove are inclined at a set or predetermined angle.

3. The display device of claim 2, wherein the side surfaces of the insulating layers defining the groove are aligned with each other.

4. The display device of claim 1, wherein a width of a space between the side surfaces of the insulating layers defining the groove increases in a direction away from the base substrate.

5. The display device of claim 1, wherein
the display pads are arranged along a first direction and a second direction intersecting the first direction,
each of the display pads extends along the second direction, and
display pads of the display pads that are sequentially arranged along the first direction define a pad row.

6. The display device of claim 5, wherein the groove comprises a plurality of grooves and each of the grooves is between adjacent display pads of the display pads arranged in the same pad row, and the grooves are spaced from each other along the first direction and the second direction.

7. The display device of claim 6, wherein widths of the grooves are measured in the first direction and vary along the second direction.

8. The display device of claim 7, further comprising pad lines connecting the display pads and the transistors and arranged between the display pads and the grooves adjacent to the display pads,
wherein a first width of a first groove among the grooves is larger than a second width of a second groove among the grooves, the first and second width measured along the first direction, and a number of the pad lines adjacent to the first groove in the first direction is less than the number of the pad lines adjacent the second groove in the first direction.

9. The display device of claim 5, wherein the groove comprises a plurality of grooves, the grooves are arranged along the first direction, and each of the grooves extends along the second direction,
the display pads are sequentially arranged along the first direction in a plurality of pad rows, the pad rows arranged along the second direction; and
when viewed in the first direction, a groove of the grooves overlaps the display pads of at least two different pad rows of the pad rows.

10. The display device of claim 5, wherein the grooves each comprise sub grooves spaced from each other along the second direction, and
the sub grooves of each of the grooves are between adjacent display pads of the display pads arranged in the same pad row.

11. The display device of claim 1, wherein the insulating layers comprise a buffer layer on the barrier layer, and first to seventh insulating layers on the buffer layer,
one of the transistors comprises a first semiconductor pattern on the buffer layer, a first control electrode on the first insulating layer and overlapping the first semiconductor pattern, and an upper electrode on the second insulating layer and overlapping the first control electrode,
another of the transistors comprises a second semiconductor pattern on the third insulating layer, and a second control electrode on the fourth insulating layer and overlapping the second semiconductor pattern,
the display device further comprises an input electrode and an output electrode on the fifth insulating layer and connected to the first and second semiconductor patterns through contact holes, and a connection electrode on the sixth insulating layer and connected to the input electrode, and
at least one of the light-emitting elements comprises a first electrode connected to the connection electrode through a contact hole in the seventh insulating layer.

12. The display device of claim 11, further comprising:
an encapsulation layer covering the display element layer, the encapsulation layer comprising inorganic layers and an organic layer between the inorganic layers, and
an input sensor directly on the encapsulation layer,
wherein the input sensor comprises a first sensing insulating layer on the encapsulation layer, a first conductive layer on the first sensing insulating layer, a second sensing insulating layer on the first sensing insulating layer, a second conductive layer on the second sensing insulating layer, and a third sensing insulating layer on the second sensing insulating layer.

13. The display device of claim 12, wherein the display pads each comprise a first pattern on the second insulating layer, a second pattern on the first pattern, a third pattern on the second pattern, and a fourth pattern on the third pattern,
the second pattern is in a first opening defined by the second to fifth insulating layers, and
the fourth pattern is in a second opening defined by first and second sensing insulating layers.

14. The display device of claim 13, wherein the first pattern comprises the same material as the first semiconductor pattern, the second pattern comprises the same material as the input electrode, the third pattern comprises the same material as the connection electrode, and the fourth pattern comprises the same material as the second conductive layer.

15. The display device of claim 14, wherein the film layer is an anisotropic conductive film (ACF) comprising a resin and conductive particles inside the resin.

16. The display device of claim 12, wherein the display pads each comprise a first conductive pattern, an insulating pattern on the first conductive pattern and comprising a polymer, and a second conductive pattern covering the insulating pattern and having two ends connected to the first conductive pattern, and
the second conductive pattern is in direct contact with a board pad of the board pads.

17. The display device of claim 16, wherein the film layer is a non-conductive film (NCF) comprising only a resin.

18. The display device of claim 1, further comprising dam patterns inside the groove and arranged along a direction in which the groove extends,
wherein the dam patterns comprise the same material as at least one of the insulating layers.

19. An electronic device comprising:
a display device comprising:
a base substrate having an active region and a peripheral region adjacent to the active region;
a circuit element layer comprising a barrier layer on the base substrate, insulating layers on the barrier layer, and transistors each comprising conductive patterns between the insulating layers;
a display element layer comprising light-emitting elements connected to the transistors;
display pads in the peripheral region and connected to the transistors;
a circuit board comprising board pads coupled to the display pads; and
a film layer between the display pads and the board pads,
wherein side surfaces of the insulating layers define a groove, the groove exposing a portion of the barrier layer and located between adjacent display pads of the display pads, and
the film layer is in contact with the portion of the barrier layer exposed by the groove.

20. The electronic device of claim 19, wherein the electronic device is a smart watch, a tablet PC, a laptop, a computer, or a smart television.
